(19) United States
(12) Patent Application Publication
(10) Pub. No.: US 2026/0371785 A1
(43) Pub. Date: Nov. 19, 2026

(54) BACK-CONTACT PHOTOVOLTAIC MODULE

(71) Applicant: ZHEJIANG JINKO SOLAR CO., LTD., Haining (CN)

(72) Inventors: Luchuang WANG, Haining (CN); Yingying PENG, Haining (CN); Ningbo ZHANG, Haining (CN); Xubing YANG, Haining (CN)

(21) Appl. No.: 19/705,390

(22) Filed: Jun. 11, 2026

Related U.S. Application Data
(63) Continuation of application No. PCT/CN2026/087598, filed on Mar. 31, 2026.

(30) Foreign Application Priority Data
May 19, 2025 (CN) 202510644790.5

(51) Int. Cl. H10F 77/00; H10F 19/90; H10F 77/30

(52) U.S. Cl. CPC H10F 77/937; H10F 19/904; H10F 19/908; H10F 77/311

(57) ABSTRACT

Provided is a back-contact photovoltaic module. The back-contact photovoltaic module includes a plurality of cell strings, at least one first ribbon, a first insulating film, a first busbar and at least one second ribbon. A cell string has a leading end and a trailing end the leading end, and includes a first solar cell at the trailing end and a second solar cell between the first solar cell and the leading end. A first ribbon extends from the first solar cell to the second solar cell along a first direction and electrically connecting the first solar cell to the second solar cell. The first insulating film is disposed over the second solar cell and located on a surface of the respective first ribbon facing away from the second solar cell. The first busbar is disposed on a side of the first insulating film facing away from the second solar cell.

### CROSS REFERENCE TO RELATED APPLICATIONS

The present application claims is a continuation of PCT Patent Application PCT/CN2026/087598, entitled “BACK-CONTACT PHOTOVOLTAIC MODULE,” filed on Mar. 31, 2026, which claims priority to Chinese Patent Application No. 202510644790.5, filed on May 19, 2025, and entitled “BACK-CONTACT PHOTOVOLTAIC MODULE,” each of which is incorporated herein by reference in its entirety.

### TECHNICAL FIELD

The present disclosure relates to the photovoltaic field, and in particular, to a back-contact photovoltaic module.

### Background

As fossil energy sources are gradually depleted, solar energy is increasingly widely used as a new alternative energy solution. A solar cell is a device that converts solar light energy into electrical energy. The solar cell utilizes the photovoltaic principle to generate carriers, and then uses electrodes to extract the carriers, thereby facilitating effective utilization of the electrical energy.

Current solar cells primarily include interdigitated back contact (IBC) cells, tunnel oxide passivated contact (TOPCON) cells, passivated emitter and rear cell (PERC) cells, heterojunction cells, and the like.

In a back-contact cell photovoltaic module, a busbar is generally disposed at an edge of the back-contact photovoltaic module to electrically connect adjacent cell strings. However, disposing the busbar at the edge of the module occupies module space, resulting in a smaller area utilization rate of the back-contact photovoltaic module and affecting the power of the back-contact photovoltaic module.

### SUMMARY

The present disclosure provides a back-contact photovoltaic module, which is at least beneficial for increasing the power of the back-contact photovoltaic module and improving the reliability of the back-contact photovoltaic module.

The present disclosure provides a back-contact photovoltaic module including: a plurality of cell strings, at least one first ribbon, a first insulating film, a first busbar, and at least one second ribbon. A cell string has a leading end and a trailing end opposite to the leading end, and includes a first solar cell disposed at the trailing end and a second solar cell between the first solar cell and the leading end. The first ribbon extends along a first direction from the trailing end to the leading end, and electrically connects the first solar cell to the second solar cell. The first insulating film is disposed over the second solar cell and on a side of the respective first ribbon facing away from the second solar cell. The first busbar is disposed on a side of the first insulating film facing away from the second solar cell. The second ribbon includes a first portion and a second portion, where the first portion is located on the first solar cell and is electrically connected to the first solar cell, and the second portion is located on the side of the first insulating film facing away from the second solar cell and is electrically connected to the first busbar.

In some embodiments, the respective second ribbon further includes a connecting portion located between the first portion and the second portion, an extension direction of the connecting portion intersects the first direction, and the second portion and the respective first ribbon on the second solar cell are spaced apart from each other along a second direction intersecting the first direction.

In some embodiments, an angle between the extension direction of the connecting portion 53 and the first direction is 20° to 90°.

In some embodiments, a length of the connecting portion along the extension direction is 5 mm to 8 mm.

In some embodiments, a distance between the second portion and an adjacent first ribbon along the second direction is 3 mm to 8 mm.

In some embodiments, a thickness of the respective second ribbon is less than or equal to a thickness of the first ribbon.

In some embodiments, a thickness of the first insulating film is 0.1 mm to 0.3 mm.

In some embodiments, the respective second ribbon is located between the first insulating film and the first busbar, the first insulating film includes a first flat portion and a first protruding portion, the first protruding portion protrudes in a direction away from the second solar cell, and the respective first ribbon is located between the first protruding portion and the second solar cell. A surface of the first protruding portion facing away from the second solar cell and a surface of the first flat portion facing away from the second solar cell form a first recess, and the respective second ribbon is located within the first recess.

In some embodiments, the first flat portion is in direct contact with the second solar cell, and the first protruding portion is lifted by the respective first ribbon and protrudes in the direction away from the second solar cell.

In some embodiments, the first busbar is located between the first insulating film and the respective second ribbon, the first insulating film includes a first flat portion and a first protruding portion, the first protruding portion protrudes in a direction away from the second solar cell, and the respective first ribbon is located between the first protruding portion and the second solar cell. The first busbar includes a second flat portion and a second protruding portion, the second flat portion is located on a surface of the first flat portion facing away from the second solar cell, the second protruding portion protrudes in a direction away from the second solar cell, the second protruding portion is located on a surface of the first protruding portion facing away from the second solar cell. A surface of the second protruding portion facing away from the second solar cell and a surface of the second flat portion facing away from the second solar cell form a second recess, and the respective second ribbon is located within the second recess.

In some embodiments, a spacing is present between the first busbar and the first solar cell.

In some embodiments, a length of the first portion along the first direction is 166 mm to 178 mm.

In some embodiments, the first insulating film includes a spacing portion and an insulating portion, the spacing portion is located between the first solar cell and the second solar cell, and the insulating portion is located over a surface of the second solar cell.

In some embodiments, the first insulating film is a transparent film layer.

In some embodiments, a width of the first insulating film along the first direction is greater than a width of the first busbar along the first direction.

In some embodiments, a width of the first insulating film along the first direction is 10 mm to 20 mm.

In some embodiments, a width of the first busbar along the first direction is 8 mm to 15 mms.

In some embodiments, the respective cell string further includes a third solar cell disposed at the leading end and a fourth solar cell connected to the third solar cell, and a first ribbon of the at least one first ribbon is configured to electrically connect the third solar cell to the fourth solar cell. The back-contact photovoltaic module further includes a second busbar, a second insulating film, and a third ribbon. The second busbar is electrically connecting third solar cells of two cell strings arranged along a second direction, the second busbar being located over the fourth solar cell. The second insulating film is disposed over the fourth solar cell and located between the second busbar and the fourth solar cell. The third ribbon includes a first part and a second part, where the first part is located on the third solar cell and is electrically connected to the third solar cell, and the second part is located on a surface of the second insulating film facing away from the fourth solar cell and is electrically connected to the second busbar.

In some embodiments, the second ribbon further includes a connecting part located between the first part and the second part, an extension direction of the connecting part intersects the first direction, and the second part and the first ribbon on the fourth solar cell are spaced apart from each other along the second direction.

In some embodiments, the back-contact photovoltaic module further includes at least one encapsulant film and at least one cover plate. The at least one encapsulant film is configured to cover surfaces of the plurality of cell strings. The at least one cover plate is configured to cover a surface of the at least one encapsulant film facing away from the plurality of cell strings.

The technical solution provided by the present disclosure has at least the following advantages.

In the back-contact photovoltaic module provided by the present disclosure, by disposing the first busbar on the surface of the second cell, the space for placing the first busbar at the edge of the back-contact photovoltaic module is saved. This allows more cells or larger-sized cells to be arranged without changing the size of the back-contact photovoltaic module, which is beneficial for improving the area utilization rate of the back-contact solar cell module and thereby increasing the power of the back-contact photovoltaic module. Moreover, the back-contact photovoltaic module further includes a first insulating film disposed between the first busbar and the first ribbon on the second cell, which can prevent a short circuit from occurring between the first ribbon electrically connected to the first busbar and the second ribbon on the second cell, thereby avoiding adverse effects on the performance of the back-contact photovoltaic module and improving the reliability of the back-contact photovoltaic module.

### BRIEF DESCRIPTION OF THE DRAWINGS

One or more embodiments are exemplarily described with reference to the corresponding figures in the accompanying drawings, and the descriptions are not to be construed as limiting the embodiments. Unless otherwise particularly stated, the figures in the accompanying drawings are not drawn to scale. To describe the technical solutions in the embodiments of the present disclosure or in the conventional technologies more clearly, the following briefly introduces the accompanying drawings required for describing the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a schematic structural diagram of a back-contact photovoltaic module according to an embodiment of the present disclosure.

FIG. 2 is a schematic structural diagram of a first solar cell, a second solar cell, and an intermediate solar cell in the back-contact photovoltaic module according to an embodiment of the present disclosure.

FIG. 3 is a schematic cross-sectional structural diagram of the second solar cell in the back-contact photovoltaic module according to an embodiment of the present disclosure.

FIG. 4 is another schematic cross-sectional structural diagram of the second solar cell in the back-contact photovoltaic module according to an embodiment of the present disclosure.

FIG. 5 is a schematic cross-sectional structural diagram of the first solar cell, the second solar cell, and a first insulating film in the back-contact photovoltaic module according to an embodiment of the present disclosure.

FIG. 6 is a schematic structural diagram of a third solar cell, a fourth solar cell, and an intermediate solar cell in the back-contact photovoltaic module according to an embodiment of the present disclosure.

FIG. 7 is a schematic cross-sectional structural diagram of the fourth solar cell in the back-contact photovoltaic module according to an embodiment of the present disclosure.

FIG. 8 is another schematic cross-sectional structural diagram of the fourth solar cell in the back-contact photovoltaic module according to an embodiment of the present disclosure.

FIG. 9 is a schematic cross-sectional structural diagram of the third solar cell, the fourth solar cell, and a second insulating film in the back-contact photovoltaic module according to an embodiment of the present disclosure.

FIG. 10 is a schematic cross-sectional structural diagram of the back-contact photovoltaic module according to an embodiment of the present disclosure.

### LIST OF REFERENCE NUMERALS

1 cell string
11 leading end
12 trailing end
13 first solar cell
14 second solar cell
15 intermediate solar cell
16 third solar cell
17 fourth solar cell
2 first ribbon
3 first insulating film
31 first flat portion
32 first protruding portion
33 spacing portion
34 insulating portion
4 first busbar
41 second flat portion
42 second protruding portion
5 second ribbon
51 first portion
52 second portion
53 connecting portion
6 second insulating film
61 first flat part
62 first protruding part
63 spacing part
64 insulating part
7 second busbar
71 second flat part
72 second protruding part
8 third ribbon
81 first part
82 second part
83 connecting part
91 encapsulant film
92 cover plate

### DETAILED DESCRIPTION OF THE EMBODIMENTS

As can be seen from the Background part, the area utilization rate of current back-contact photovoltaic modules is small, resulting in a need to improve the power of the back-contact photovoltaic modules.

Embodiments of the present disclosure provide a back-contact photovoltaic module. By disposing the first busbar on the surface of the second solar cell, space for placing the first busbar at the edge of the back-contact photovoltaic module is saved, so that under a condition that a size of the back-contact photovoltaic module remains unchanged, more solar cells may be placed or solar cells of a larger size may be adopted, which is beneficial for increasing an area utilization rate of the back-contact solar cell module, thereby increasing the power of the back-contact photovoltaic module. In addition, in the back-contact photovoltaic module, the first insulating film is further provided between the first busbar and the first ribbon on the second solar cell, which can avoid a short circuit between the first ribbon electrically connected to the first busbar and the second ribbon on the second solar cell that would affect the performance of the back-contact photovoltaic module, thereby improving the reliability of the back-contact photovoltaic module.

In the description of the embodiments of the present disclosure, technical terms such as “first,” “second,” and the like are only used to distinguish different objects and shall not be construed as indicating or implying relative importance, or implicitly specifying the number, specific order, or primary-secondary relationship of the indicated technical features. In the description of the embodiments of the present disclosure, “a plurality of” means two or more, unless otherwise explicitly and specifically defined.

Mention of “embodiment” herein means that a particular feature, structure, or characteristic described in connection with the embodiment can be included in at least one embodiment of the present disclosure. The appearances of the phrase in various places in the specification are not necessarily all referring to the same embodiment, nor are separate or alternative embodiments mutually exclusive of other embodiments. Those skilled in the art understand, explicitly and implicitly, that the embodiments described herein can be combined with other embodiments.

In the description of the embodiments of the present disclosure, the term “and/or” is merely an associative relationship describing associated objects, indicating that three relationships can exist, for example, A and/or B can represent: A alone, both A and B, and B alone. In addition, the character “/” herein generally indicates that the associated objects are in an “or” relationship.

In the description of the embodiments of the present disclosure, the term “a plurality of” refers to two or more (including two). Similarly, “a plurality of groups” refers to two or more groups (including two groups), and “a plurality of pieces” refers to two or more pieces (including two pieces).

In the description of the embodiments of the present disclosure, technical terms such as “center,” “longitudinal,” “transverse,” “length,” “width,” “thickness,” “up,” “down,” “front,” “back,” “left,” “right,” “vertical,” “horizontal,” “top,” “bottom,” “inner,” “outer,” “clockwise,” “counterclockwise,” “axial,” “radial,” “circumferential,” and the like indicate orientations or positional relationships based on the orientations or positional relationships shown in the drawings. These terms are only for the convenience of describing the embodiments of the present disclosure and simplifying the description, and do not indicate or imply that the referred devices or elements must have a specific orientation, be constructed and operated in a specific orientation, and therefore shall not be construed as limiting the embodiments of the present disclosure.

In the description of the embodiments of the present disclosure, unless otherwise explicitly specified and defined, technical terms such as “mounted,” “connected,” “coupled,” “fixed,” and the like should be understood in a broad sense, for example, it may be a fixed connection, a detachable connection, or an integral formation; it may be a mechanical connection or an electrical connection; it may be a direct connection or an indirect connection via an intermediate medium, and it may be internal communication between two elements or an interaction relationship between two elements. For those of ordinary skill in the art, the specific meanings of the above terms in the embodiments of the present disclosure may be understood according to specific situations.

In the description of the embodiments of the present disclosure, electrical connection between one component and another component means that materials of both components are conductive materials, and the two components are in direct contact and connected or are connected via other conductive materials, so that when the photovoltaic module is in a power generation state, current transfer exists between the two components.

In the drawings corresponding to the embodiments of the present disclosure, thicknesses and areas of layers are exaggerated for better understanding and ease of description. When a component (such as a layer, film, region, or substrate) is described as being “on” another component or “on a surface of “another component, the component may be “directly” on the surface of the another component, or a third component may be present between the two components. Conversely, when a component is described as being “on a surface of” another component or “formed” or “provided” with another component on the surface thereof, this indicates that there is no third component between the two components. In addition, when a component is described as being “substantially” formed on another component, it means that the component is not formed on the entire surface (or front surface) of the another component, nor on a partial edge of the entire surface.

In the description of the embodiments of the present disclosure, when a component “includes” another component, unless otherwise stated, it does not exclude other components, and other components may further be included. In addition, when components such as layers, films, regions, or plates are referred to as being “on/located on” another component, they may be “directly on” the another component (i.e., located on the surface of the another component without any other component therebetween), or another component can exist therebetween. In addition, when components such as layers, films, regions, or plates are “directly on” another component, or when components such as layers, films, regions, or plates are located on a surface of another component, it means that no other component is located therebetween.

Various embodiments of the present disclosure will be described in detail below with reference to the accompanying drawings. However, those of ordinary skill in the art can understand that in the embodiments of the present disclosure, many technical details are set forth for the reader to better understand the present disclosure. However, even without these technical details and based on various changes and modifications of the following embodiments, the technical solutions claimed in the present disclosure can still be realized.

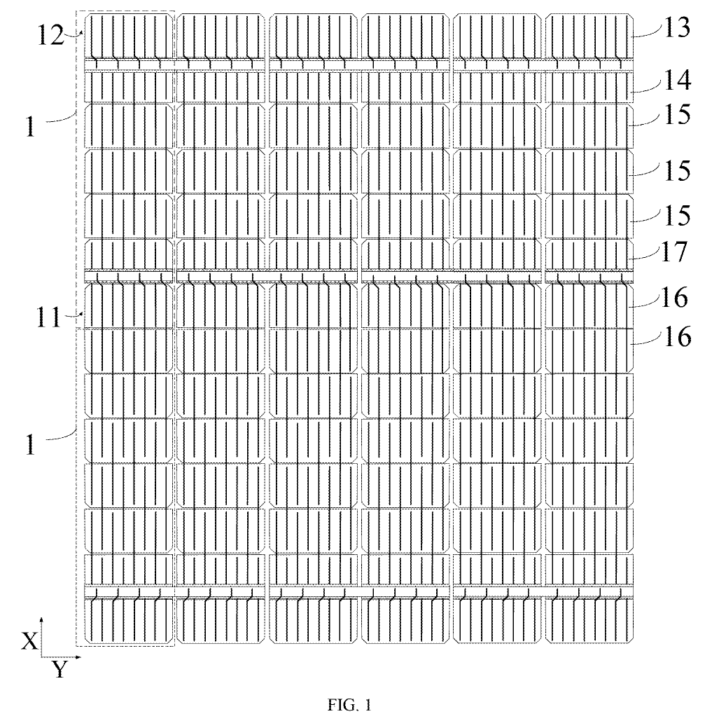

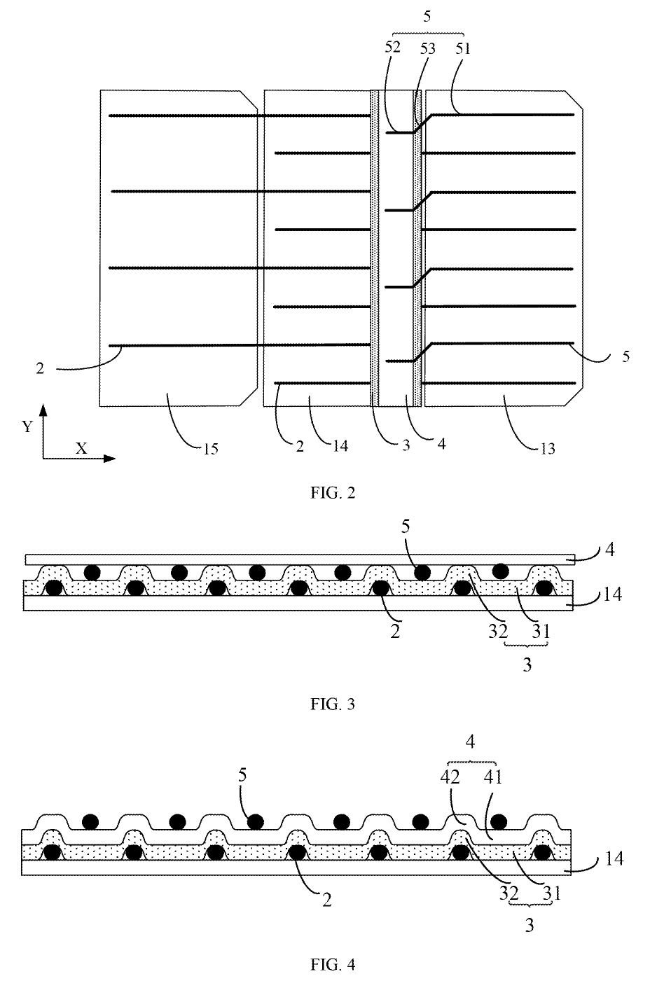

FIG. 1 is a schematic structural diagram of a back-contact photovoltaic module according to an embodiment of the present disclosure, and FIG. 2 is a schematic structural diagram of a first solar cell, a second solar cell, and an intermediate solar cell in the back-contact photovoltaic module according to an embodiment of the present disclosure.

Referring to FIGS. 1 and 2 , the back-contact photovoltaic module includes a plurality of cell strings 1, a first ribbon 2, a first insulating film 3, a first busbar 4, and a second ribbon 5. A cell string 1 has a leading end 11 and a trailing end 12 the leading end 11, and includes a first solar cell 13 at the trailing end 12 and a second solar cell 14 between the first solar cell 13 and the leading end 11. The first ribbon 2 extends along a first direction X and electrically connects the first solar cell 13 to the second solar cell 14. The first insulating film 3 is located on the second solar cell 14 and on a side of the first ribbon 2 facing away from the second solar cell 14. The first busbar 4 is located on a side of the first insulating film 3 facing away from the second solar cell 14. The second ribbon 5 includes a first portion 51 and a second portion 52, the first portion 51 is located on the first solar cell 13 and is electrically connected to the first solar cell 13, and the second portion 52 is located on the side of the first insulating film 3 facing away from the second solar cell 14 and is electrically connected to the first busbar 4.

The cell string 1 includes a plurality of solar cells connected in series.

In some embodiments, solar cells in the cell string 1 may be IBC cells, hybrid passivated back contact (HPBC) cells, TBC cells combining TOPCON technology and IBC technology, HBC cells combining heterojunction technology and IBC technology, or other types of back-contact cells.

In some embodiments, adjacent solar cells in the cell string 1 are arranged at intervals. In other embodiments, adjacent solar cells in the cell string 1 may be partially overlapped, such as in a shingled module.

The cell string 1 includes the first solar cell 13, the second solar cell 14, and an intermediate solar cell 15. The first solar cell 13 is disposed at the trailing end 12 of the cell string 1, the second solar cell 14 is located between the first solar cell 13 and the intermediate solar cells 15, and the second solar cell 14 is electrically connected to the first solar cell 13 and to the intermediate solar cells 15.

The solar cell may be a full cell or a segmented cell. The segmented cell refers to a cell formed by cutting a complete full cell through a cutting process. The segmented cell may be a half-cut cell, a one-third cut cell, a one-fourth cut cell, or the like.

The solar cell may be provided with a chamfer (not labeled), which can effectively reduce stress concentration at an edge of the solar cell and reduce risks of mechanical damage such as breakage and micro-cracks of the solar cell caused by stress concentration.

The first ribbon 2 is a series ribbon used for electrically connecting the first solar cell 13 and the second solar cell 14, also used for electrically connecting the second solar cell 14 and the intermediate solar cell 15, and for electrically connecting other adjacent intermediate solar cells 15.

In some embodiments, the first ribbon 2 may include a first series ribbon (not labeled) and a second series ribbon (not labeled). In the second direction Y, the first series ribbon and the second series ribbon are arranged in a staggered manner. In one cell string 1, an Nₜₕ solar cell, an (N+1)ₜₕ solar cell, and an (N+2)ₜₕ solar cell (N is a positive integer greater than 1) are sequentially arranged along the first direction X. Positive electrode fingers of the Nₜₕ solar cell are electrically connected to negative electrode fingers of the (N+1)ₜₕ solar cell via a plurality of first series ribbons, and positive electrode fingers of the (N+1)ₜₕ solar cell are electrically connected to negative electrode fingers of the (N+2)ₜₕ solar cell via a plurality of second series ribbons.

The second ribbon 5 is used for electrically connecting the first solar cell 13 to the first busbar 4. Specifically, in the second ribbon 5, the first portion 51 is located over the first solar cell 13 for electrical connection with the first solar cell 13, and the second portion 52 is located over the second solar cell 14 for electrical connection with the first busbar 4.

In some embodiments, a length of the first portion 51 along the first direction X is 166 mm to 178 mm, for example, 166 mm, 168 mm, 170 mm, 172 mm, 174 mm, or 178 mm. A length of the second portion 52 along the first direction X is 8 mm to 15 mm, for example, 8 mm, 10 mm, 12 mm, or 15 mm.

The first busbar 4 is used for electrically connecting adjacent cell strings 1. In an example, a part of the first busbar 4 is electrically connected to the first solar cell 13 on one cell string 1 via one second ribbon 5, and another part of the first busbar 4 is electrically connected to the first solar cell 13 on another cell string 1 via another second ribbon 5.

A spacing is present between the first busbar 4 and the first solar cell 13, that is, the first busbar 4 is not on the first solar cell 13. This can avoid the situation where disposing a part of the first busbar 4 on the first solar cell 13 reduces a contact area between the second ribbon 5 and the first solar cell 13, which affecting current collection efficiency of the second ribbon 5. That is, the spacing present between the first busbar 4 and the first solar cell 13 enables a larger contact area between the second ribbon 5 and the first solar cell 13, which can improve the current collection efficiency of the second ribbon 5, thereby enhancing the performance of the back-contact photovoltaic module.

The first insulating film 3 is located between the first busbar 4 and the second solar cell 14, which can avoid a short circuit between the first ribbon 2 and the second ribbon 5 that would affect the performance of the back-contact photovoltaic module, thereby improving the reliability of the back-contact photovoltaic module.

In some embodiments, after the first ribbon 2 is laid on the solar cell, the first insulating film 3 is laid; then, the first busbar 4 and the second ribbon 5 are welded together, and the welded assembly of the first busbar 4 and the second ribbon 5 is laid on the solar cell. In other embodiments, after the first ribbon 2 is laid on the solar cell, the first insulating film 3 and the second ribbon 5 are laid on the solar cell, and then the first busbar 4 is welded onto the second ribbon 5. In still other embodiments, after the first ribbon 2 is laid on the solar cell, the first insulating film 3, the first busbar 4, and the second ribbon 5 are connected first, and then the connected assembly of the first insulating film 3, the first busbar 4, and the second ribbon 5 is laid on the solar cell.

In some embodiments, the second ribbon 5 further includes a connecting portion 53, where the connecting portion 53 is located between the first portion 51 and the second portion 52, and an extension direction of the connecting portion 53 intersects the first direction X. The second portion 52 and the first ribbon 2 on the second solar cell 14 are spaced apart from each other along the second direction Y.

The extension direction of the connecting portion 53 intersects the first direction X, that is, the extension direction of the connecting portion 53 intersects the extension direction of the first portion 51 and intersects the extension direction of the second portion 52, so as to realize that the second portion 52 and the first ribbon 2 on the second solar cell 14 are spaced apart from each other along the second direction Y, that is, do not overlap.

The first ribbon 2 on the second solar cell 14 and the second portion 52 being spaced apart from each other along the second direction Y can avoid the situation where the second portion 52 and a part of the first ribbon 2 on the second solar cell 14 are located on the same straight line, which would cause that part of the first ribbon 2 to lift the second portion 52, making the second portion 52 higher relative to the first portion 51 and pulling the first portion 51, resulting in displacement of the first portion 51 that affects the performance of the back-contact photovoltaic module. Furthermore, this arrangement can also avoid the situation where a part of the first ribbon 2 lifts the second portion 52, making the second portion 52 too high, which would cause stress concentration on the higher second portion 52 during subsequent lamination of the cell string 1 with an encapsulant film and a cover plate, leading to breakage of the solar cell.

In some embodiments, the extension direction of the connecting portion 53 intersects the first direction X, and an angle between the extension direction of the connecting portion 53 and the first direction X is 20° to 90°, for example, 20° to 45°, 45° to 70°, or 70° to 90°. Exemplarily, the angle between the extension direction of the connecting portion 53 and the first direction X may be 20°, 32.5°, 45°, 55°, 57.5°, 70°, 80°, or 90°.

When the angle between the extension direction of the connecting portion 53 and the first direction X is 90°, the extension direction of the connecting portion 53 may be parallel to the second direction Y.

In some embodiments, a length of the connecting portion 53 along the extension direction thereof is 5 mm to 8 mm, for example, 5 mm, 5.5 mm, 6 mm, 6.5 mm, 7 mm, 7.5 mm, or 8 mm.

In some embodiments, a distance between the second portion 52 and an adjacent first ribbon 2 along the second direction Y is 3 mm to 8 mm, for example, 3 mm to 5 mm, 5 mm to 6 mm, or 6 mm to 8 mm. In some embodiments, the distance may be 3 mm, 3.5 mm, 4 mm, 4.5 mm, 5 mm, 5.5 mm, 6 mm, 6.5 mm, 7 mm, 7.5 mm, or 8 mm. When the distance between the second portion 52 and the adjacent first ribbon 2 along the second direction Y is within the above range, a short circuit caused by an excessively close distance between the second portion 52 and the adjacent first ribbon 2, which would affect the performance of the back-contact photovoltaic module, can be avoided.

FIG. 3 is a schematic cross-sectional structural diagram of the second solar cell in the back-contact photovoltaic module according to an embodiment of the present disclosure.

Referring to FIGS. 1-3 , in some embodiments, the second ribbon 5 is located between the first insulating film 3 and the first busbar 4. The first insulating film 3 includes a first flat portion 31 and a first protruding portion 32, the first protruding portion 32 protrudes in a direction away from the second solar cell 14 relative to the first flat portion 31. The first ribbon 2 is located between the first protruding portion 32 and the second solar cell 14. A surface of the first protruding portion 32 facing away from the second solar cell 14 and a surface of the first flat portion 31 facing away from the second solar cell 14 form a first recess, and the second ribbon 5 is located within the first recess.

By configuring the first insulating film 3 to include the first flat portion 31 and the first protruding portion 32 as described, and by disposing the second ribbon 5 within the first recess, the height of the second portion 52 of the second ribbon 5 relative to the second solar cell 14 can be made lower. This avoids the situation where a larger height of the second portion 52 of the second ribbon 5 relative to the second solar cell 14 would pull the first portion 51 located on the first solar cell 13 and cause displacement of the first portion 51 affecting the performance of the back-contact photovoltaic module. Furthermore, this arrangement can also avoid the situation where the larger height of the second portion 52 of the second ribbon 5 relative to the second solar cell 14 would cause stress concentration on the higher second portion 52 during subsequent lamination of the cell string 1 with an encapsulant film and a cover plate, leading to breakage of the solar cell.

The first flat portion 31 is in direct contact with the second solar cell 14, and the first protruding portion 32 is lifted by the first ribbon 2 and protrudes in the direction away from the second solar cell 14 relative to the first flat portion 31. Surfaces of two adjacent first protruding portions 32 facing away from the second solar cell 14 and the surface of the first flat portion 31 (located between the two adjacent first protruding portions 32) facing away from the second solar cell 14 form the first recess.

In some embodiments, a thickness of the second ribbon 5 is less than or equal to a thickness of the first ribbon 2. That is, the thickness of the first ribbon 2 may be larger, so that the first ribbon 2 lifts the first protruding portion 32 of the first insulating film 3 to a greater height, enabling the first recess formed by the surface of the first protruding portion 32 facing away from the second solar cell 14 and the surface of the first flat portion 31 facing away from the second solar cell 14 to completely accommodate the second portion 52. Here, “completely accommodate” means that a height difference between the surface of the first protruding portion 32 facing away from the second solar cell 14 and the surface of the first flat portion 31 facing away from the second solar cell 14 may be greater than or equal to the thickness of the second portion 52 of the second ribbon 5.

In some embodiments, the thickness of the first ribbon 2 is 0.1 mm to 0.28 mm, for example, 0.1 mm, 0.12 mm, 0.15 mm, 0.18 mm, 0.2 mm, 0.24 mm, or 0.28 mm.

The thickness of the second ribbon 5 is 0.1 mm to 0.28 mm, for example, 0.1 mm, 0.12 mm, 0.15 mm, 0.18 mm, 0.2 mm, 0.24 mm, or 0.28 mm.

In some embodiments, a thickness of the first insulating film 3 is 0.1 mm to 0.3 mm, for example, 0.1 mm, 0.12 mm, 0.15 mm, 0.18 mm, 0.2 mm, 0.25 mm, or 0.3 mm.

FIG. 4 is another schematic cross-sectional structural diagram of the second solar cell in the back-contact photovoltaic module according to an embodiment of the present disclosure.

Referring to FIGS. 1,2 and 4, in some embodiments, the first busbar 4 is located between the first insulating film 3 and the second ribbon 5. The first insulating film 3 includes a first flat portion 31 and a first protruding portion 32, the first protruding portion 32 protrudes in a direction away from the second solar cell 14 relative to the first flat portion 31. The first ribbon 2 is located between the first protruding portion 32 and the second solar cell 14. The first busbar 4 includes a second flat portion 41 and a second protruding portion 42, the second flat portion 41 is located on a surface of the first flat portion 31 facing away from the second solar cell 14, the second protruding portion 42 protrudes in a direction away from the second solar cell 14 relative to the second flat portion 41, and the second protruding portion 42 is located on a surface of the first protruding portion 32 facing away from the second solar cell 14. A surface of the second protruding portion 42 facing away from the second solar cell 14 and a surface of the second flat portion 41 facing away from the second solar cell 14 form a second recess, and the second ribbon 5 is located within the second recess.

The surface of the second protruding portion 42 facing away from the second solar cell 14 and the surface of the second flat portion 41 facing away from the second solar cell 14 form the second recess. Specifically, two adjacent second protruding portions 42 and the second flat portion 41 located between the two adjacent second protruding portions 42 form the second recess.

By configuring the first insulating film 3 to include the first flat portion 31 and the first protruding portion 32, and simultaneously configuring the first busbar 4 to include the second flat portion 41 and the second protruding portion 42, the first busbar 4 and the first insulating film 3 may be in close contact with each other, thereby improving the structural stability of the back-contact photovoltaic module. In addition, by disposing the second ribbon 5 within the second recess formed by the second flat portion 41 and the second protruding portion 42, the height of the second portion 52 of the second ribbon 5 relative to the second solar cell 14 may be made lower. This avoids the situation where a larger height of the second portion 52 of the second ribbon 5 relative to the second solar cell 14 would pull the first portion 51 located on the first solar cell 13 and cause displacement of the first portion 51 affecting the performance of the back-contact photovoltaic module. Furthermore, this arrangement can also avoid the situation where the larger height of the second portion 52 of the second ribbon 5 relative to the second solar cell 14 would cause stress concentration on the higher second portion 52 during subsequent lamination of the cell string 1 with an encapsulant film and a cover plate, leading to breakage of the solar cell.

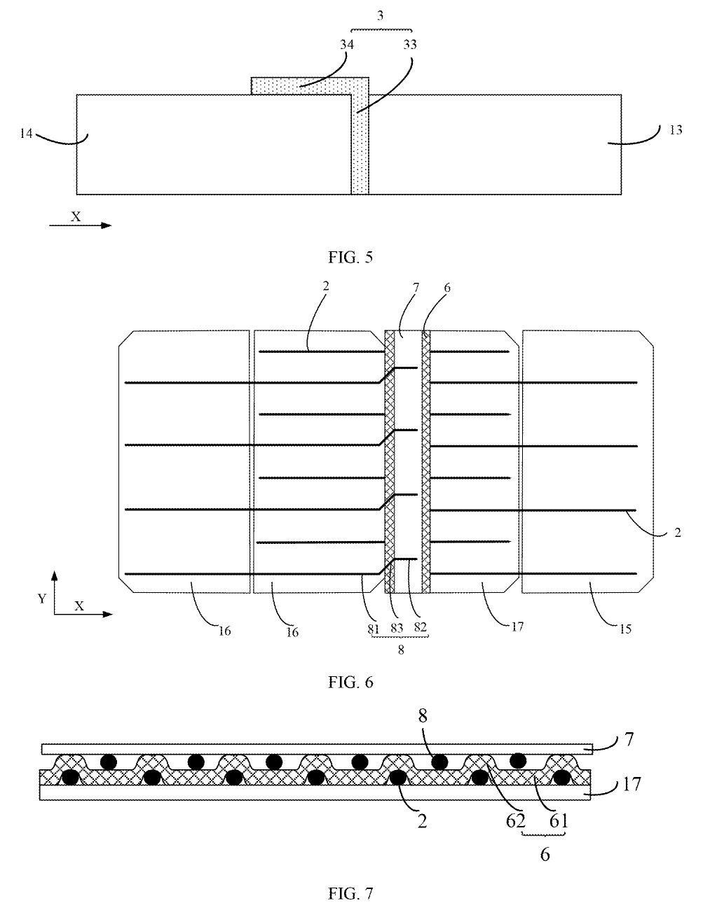

FIG. 5 is a schematic cross-sectional structural diagram of the first solar cell, the second solar cell, and the first insulating film in the back-contact photovoltaic module according to an embodiment of the present disclosure.

Referring to FIGS. 1,2 and 5, in some embodiments, the first insulating film 3 includes a spacing portion 33 and an insulating portion 34, the spacing portion 33 is located between the first solar cell 13 and the second solar cell 14, and the insulating portion 34 is located on a surface of the second solar cell 14. The spacing portion 33 is located between the first solar cell 13 and the second solar cell 14, and can serve as a buffer layer between the first solar cell 13 and the second solar cell 14 to avoid collision due to an excessively close distance between the first solar cell 13 and the second solar cell 14. At the same time, the spacing portion 33 can also realize mutual insulation between the first solar cell 13 and the second solar cell 14. In this way, this can facilitate further shortening the distance between the first solar cell 13 and the second solar cell 14, thereby improving the area utilization rate of the back-contact photovoltaic module.

The insulating portion 34 is located on the surface of the second solar cell 14 to insulate the first busbar 4 from the first ribbon 2.

In some embodiments, the first insulating film 3 is a transparent film layer. In this way, more sunlight can pass through the first insulating film 3 and be absorbed by the solar cell, which is beneficial for improving the performance of the back-contact photovoltaic module.

With continued reference to FIGS. 1 and 2 , in some embodiments, a width of the first insulating film 3 along the first direction X is greater than a width of the first busbar 4 along the first direction X. In this way, the width of the first insulating film 3 is relatively large, which can effectively achieve electrical isolation between the first busbar 4 and the first ribbon 2.

In some embodiments, the width of the first insulating film 3 along the first direction X is 10 mm to 20 mm, for example, 10 mm, 12 mm, 14 mm, 16 mm, 18 mm, or 20 mm. When the width of the first insulating film 3 is within the above range, the first insulating film 3 can effectively isolate the first busbar 4 from the first ribbon 2 on the second solar cell 14, and can also avoid problems such as affecting sunlight absorption by the second solar cell 14 and cost increase caused by an excessively wide first insulating film 3.

The width of the first busbar 4 along the first direction X is 8 mm to 15 mm, for example, 8 mm, 10 mm, 12 mm, 14 mm, or 15 mm.

FIG. 6 is a schematic structural diagram of a third solar cell, a fourth solar cell, and an intermediate solar cell in the back-contact photovoltaic module according to an embodiment of the present disclosure.

Referring to FIGS. 1 and 6 , in some embodiments, the cell string 1 further includes a third solar cell 16 disposed at the leading end 11 and a fourth solar cell 17 connected to the third solar cell 16, and the first ribbon 2 further electrically connects the third solar cell 16 to the fourth solar cell 17. The back-contact photovoltaic module further includes a second busbar 7, a second insulating film 6, and a third ribbon 8. The second busbar 7 electrically connects third solar cells 16 of two cell strings 1 arranged along the second direction Y, and the second busbar 7 is located over the fourth solar cell 17. The second insulating film 6 is located on the fourth solar cell 17 and is located between the second busbar 7 and the fourth solar cell 17. The third ribbon 8 includes a first part 81 and a second part 82, the first part 81 is located on the third solar cell 16 and is electrically connected to the third solar cell 16, and the second part 82 is located on a surface of the second insulating film 6 facing away from the fourth solar cell 17 and is electrically connected to the second busbar 7.

By disposing the second busbar 7 on the surface of the fourth solar cell 17, space for placing the second busbar 7 in the back-contact photovoltaic module is saved, so that under a condition that a size of the back-contact photovoltaic module remains unchanged, more solar cells can be placed or solar cells of a larger size can be adopted, which is beneficial for increasing an area utilization rate of the back-contact solar cell module, thereby increasing the power of the back-contact photovoltaic module. In addition, in the back-contact photovoltaic module, the second insulating film 6 is provided between the second busbar 7 and the first ribbon 2 on the fourth solar cell 17, which can avoid a short circuit between the third ribbon 8 electrically connected to the second busbar 7 and the first ribbon 2 on the fourth solar cell 17 that would affect the performance of the back-contact photovoltaic module, thereby improving the reliability of the back-contact photovoltaic module.

The third solar cell 16 is disposed at the leading end 11 of the cell string 1, the fourth solar cell 17 is located between the third solar cell 16 and the intermediate solar cell 15, and the fourth solar cell 17 is electrically connected to the third solar cell 16 and to the intermediate solar cell 15.

The first ribbon 2 is further used for electrically connecting the third solar cell 16 to the fourth solar cell 17, and electrically connecting the fourth solar cell 17 to the intermediate solar cell 15.

The third ribbon 8 is used for electrically connecting the third solar cell 16 to the second busbar 7. Specifically, the first part 81 of the third ribbon 8 is located on the third solar cell 16 for electrical connection with the third solar cell 16, and the first part 81 is electrically connected to third solar cells 16 of two cell strings 1 arranged along the second direction Y. The second part 82 is located on the fourth solar cell 17 for electrical connection with the second busbar 7.

The second busbar 7 electrically connects third solar cells 16 located at the leading ends 11 of the two cell strings 1 arranged along the second direction Y, so as to connect adjacent cell strings 1 in parallel.

A spacing is present between the second busbar 7 and the third solar cell 16, that is, the second busbar 7 is not on the third solar cell 16. This can avoid the situation where disposing a part of the second busbar 7 on the third solar cell 16 reduces a contact area between the third ribbon 8 and the third solar cell 16, thereby affecting current collection efficiency of the third ribbon 8. That is, the spacing present between the second busbar 7 and the third solar cell 16 enables a larger contact area between the third ribbon 8 and the third solar cell 16, which can improve the current collection efficiency of the third ribbon 8, thereby enhancing the performance of the back-contact photovoltaic module.

The second insulating film 6 is located between the second busbar 7 and the fourth solar cell 17, which can avoid a short circuit between the first ribbon 2 and the third ribbon 8 that would affect the performance of the back-contact photovoltaic module, thereby improving the reliability of the back-contact photovoltaic module.

In some embodiments, the third ribbon 8 further includes a connecting part 83, the connecting part 83 is located between the first part 81 and the second part 82, and an extension direction of the connecting part 83 intersects the first direction X. The second part 82 and the first ribbon 2 on the fourth solar cell 17 are spaced apart from each other along the second direction Y.

The extension direction of the connecting part 83 intersects the first direction X, that is, the extension direction of the connecting part 83 intersects the extension direction of the first part 81 and intersects the extension direction of the second part 82, so as to realize that the second part 82 and the first ribbon 2 on the fourth solar cell 17 are spaced apart from each other along the second direction Y.

The second part 82 and the first ribbon 2 on the fourth solar cell 17 being spaced apart from each other along the second direction Y can avoid the situation where the second part 82 and a part of the first ribbon 2 on the fourth solar cell 17 are located on the same straight line, which would cause that part of the first ribbon 2 to lift the second part 82, making the second part 82 higher relative to the first part 81 and pulling the first part 81, resulting in displacement of the first part 81 that affects the performance of the back-contact photovoltaic module. Furthermore, this arrangement can also avoid the situation where a part of the first ribbon 2 lifts the second part 82, making the second part 82 too high, which would cause stress concentration on the higher second part 82 during subsequent lamination of the cell string 1 with an encapsulant film and a cover plate, leading to breakage of the solar cell.

In some embodiments, the extension direction of the connecting part 83 intersects the first direction X, and an angle between the extension direction of the connecting part 83 and the first direction X is 20° to 90°, for example, 20° to 45°, 45° to 70°, or 70° to 90°. Exemplarily, the angle between the extension direction of the connecting part 83 and the first direction X may be 20°, 32.5°, 45°, 55°, 57.5°, 70°, 80°, or 90°.

When the angle between the extension direction of the connecting part 83 and the first direction X is 90°, the extension direction of the connecting part 83 may be parallel to the second direction Y.

In some embodiments, a distance between the second part 82 and an adjacent first ribbon 2 along the second direction Y is 3 mm to 8 mm, for example, 3 mm to 5 mm, 5 mm to 6 mm, or 6 mm to 8 mm. In some embodiments, the distance may be 3 mm, 3.5 mm, 4 mm, 4.5 mm, 5 mm, 5.5 mm, 6 mm, 6.5 mm, 7 mm, 7.5 mm, or 8 mm. When the distance between the second part 82 and the adjacent first ribbon 2 along the second direction Y is within the above range, a short circuit caused by an excessively close distance between the second part 82 and the adjacent first ribbon 2, which would affect the performance of the back-contact photovoltaic module, can be avoided.

FIG. 7 is a schematic cross-sectional structural diagram of the fourth solar cell in the back-contact photovoltaic module according to an embodiment of the present disclosure.

Referring to FIGS. 1,6 and 7, in some embodiments, the third ribbon 8 is located between the second insulating film 6 and the second busbar 7. The second insulating film 6 includes a first flat part 61 and a first protruding part 62, the first protruding part 62 protrudes in a direction away from the fourth solar cell 17 relative to the first flat part 61, and the first ribbon 2 is located between the first protruding part 62 and the fourth solar cell 17. A surface of the first protruding part 62 facing away from the fourth solar cell 17 and a surface of the first flat part 61 facing away from the fourth solar cell 17 form a first recessed part, and the third ribbon 8 is located within the first recessed part. By configuring the second insulating film 6 to include the first flat part 61 and the first protruding part 62, and by disposing the third ribbon 8 within the first recessed part formed by the first flat part 61 and the first protruding part 62, the height of the second part 82 of the third ribbon 8 relative to the fourth solar cell 17 can be made lower. This avoids the situation where a larger height of the second part 82 of the third ribbon 8 relative to the fourth solar cell 17 would pull the first part 81 located on the third solar cell 16 and cause displacement of the first part 81 affecting the performance of the back-contact photovoltaic module. Furthermore, this arrangement can also avoid the situation where the larger height of the second part 82 of the third ribbon 8 relative to the fourth solar cell 17 would cause stress concentration on the higher second part 82 during subsequent lamination of the cell string 1 with an encapsulant film and a cover plate, leading to breakage of the solar cell.

The first flat part 61 is in direct contact with the fourth solar cell 17, and the first protruding part 62 is lifted by the first ribbon 2 and protrudes in the direction away from the fourth solar cell 17 relative to the first flat part 61. Surfaces of two adjacent first protruding parts 62 facing away from the fourth solar cell 17 and the surface of the first flat part 61 located between the two adjacent first protruding parts 62 facing away from the fourth solar cell 17 form the first recessed part.

In some embodiments, a thickness of the third ribbon 8 is less than or equal to a thickness of the first ribbon 2. That is, the thickness of the first ribbon 2 can be larger, so that the first ribbon 2 lifts the first protruding part 62 of the second insulating film 6 to a greater height, enabling the first recessed part formed by the surface of the first protruding part 62 facing away from the fourth solar cell 17 and the surface of the first flat part 61 facing away from the fourth solar cell 17 to completely accommodate the second part 82. Here, “completely accommodate” means that a height difference between the surface of the first protruding part 62 facing away from the fourth solar cell 17 and the surface of the first flat part 61 facing away from the fourth solar cell 17 may be greater than or equal to the thickness of the second part 82 of the third ribbon 8.

In some embodiments, the thickness of the first ribbon 2 is 0.1 mm to 0.28 mm, for example, 0.1 mm, 0.12 mm, 0.15 mm, 0.18 mm, 0.2 mm, 0.24 mm, or 0.28 mm.

In some embodiments, the thickness of the third ribbon 8 is 0.1 mm to 0.28 mm, for example, 0.1 mm, 0.12 mm, 0.15 mm, 0.18 mm, 0.2 mm, 0.24 mm, or 0.28 mm.

In some embodiments, a thickness of the second insulating film 6 is 0.1 mm to 0.3 mm, for example, 0.1 mm, 0.12 mm, 0.15 mm, 0.18 mm, 0.2 mm, 0.25 mm, or 0.3 mm.

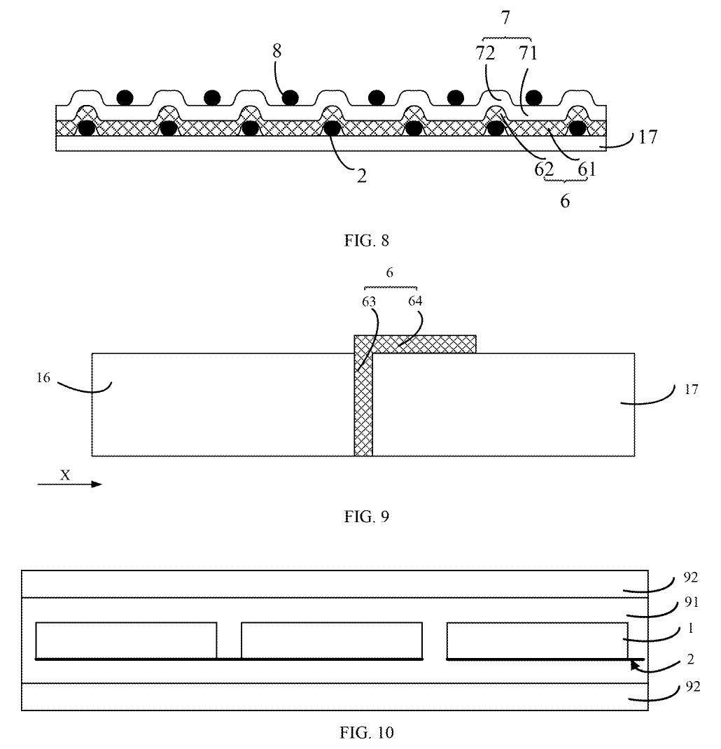

FIG. 8 is another schematic cross-sectional structural diagram of the fourth solar cell in the back-contact photovoltaic module according to an embodiment of the present disclosure.

Referring to FIGS. 1,6 and 8, in some embodiments, the second busbar 7 is located between the second insulating film 6 and the third ribbon 8. The second insulating film 6 includes a first flat part 61 and a first protruding part 62, the first protruding part 62 protrudes in a direction away from the fourth solar cell 17 relative to the first flat part 61, and the first ribbon 2 is located between the first protruding part 62 and the fourth solar cell 17. The second busbar 7 includes a second flat part 71 and a second protruding part 72, the second flat part 71 is located on a surface of the first flat part 61 facing away from the fourth solar cell 17, the second protruding part 72 protrudes in a direction away from the fourth solar cell 17 relative to the second flat part 71, and the second protruding part 72 is located on a surface of the first protruding part 62 facing away from the fourth solar cell 17. A surface of the second protruding part 72 facing away from the fourth solar cell 17 and a surface of the second flat part 71 facing away from the fourth solar cell 17 form a second recessed part (not labeled), and the third ribbon 8 is located within the second recessed part.

The surface of the second protruding part 72 facing away from the fourth solar cell 17 and the surface of the second flat part 71 facing away from the fourth solar cell 17 form the second recessed part. Specifically, two adjacent second protruding parts 72 and the second flat part 71 located between the two adjacent second protruding parts 72 form the second recessed part.

By configuring the second insulating film 6 to include the first flat part 61 and the first protruding part 62, and simultaneously configuring the second busbar 7 to include the second flat part 71 and the second protruding part 72, the second busbar 7 and the second insulating film 6 may be in close contact with each other, thereby improving the structural stability of the back-contact photovoltaic module. In addition, by disposing the third ribbon 8 within the second recessed part formed by the second flat part 71 and the second protruding part 72, the height of the second part 82 of the third ribbon 8 relative to the fourth solar cell 17 can be made lower. This avoids the situation where a greater height of the second part 82 of the third ribbon 8 relative to the fourth solar cell 17 would pull the first part 81 located on the third solar cell 16 and cause displacement of the first part 81 affecting the performance of the back-contact photovoltaic module. Furthermore, this arrangement can also avoid the situation where the greater height of the second part 82 of the third ribbon 8 relative to the fourth solar cell 17 would cause stress concentration on the higher second part 82 during subsequent lamination of the cell string 1 with an encapsulant film and a cover plate, leading to breakage of the solar cell.

FIG. 9 is a schematic cross-sectional structural diagram of the third solar cell, the fourth solar cell, and the second insulating film in the back-contact photovoltaic module according to an embodiment of the present disclosure.

Referring to FIGS. 1,6 and 9, in some embodiments, the second insulating film 6 includes a spacing part 63 and an insulating part 64, the spacing part 63 is located between the third solar cell 16 and the fourth solar cell 17, and the insulating part 64 is located on a surface of the fourth solar cell 17. The spacing part 63 is located between the third solar cell 16 and the fourth solar cell 17, and can serve as a buffer layer between the third solar cell 16 and the fourth solar cell 17 to avoid collision due to an excessively close distance between the third solar cell 16 and the fourth solar cell 17. At the same time, the spacing part 63 can also realize mutual insulation between the third solar cell 16 and the fourth solar cell 17. In this way, this can facilitate further shortening the distance between the third solar cell 16 and the fourth solar cell 17, thereby improving the area utilization rate of the back-contact photovoltaic module.

The insulating part 64 is located on the surface of the fourth solar cell 17 and is used for insulating the second busbar 7 from the first ribbon 2.

In some embodiments, the second insulating film 6 is a transparent film layer. In this way, more light can pass through the second insulating film 6 and be absorbed by the fourth solar cell 17, which is beneficial for improving the performance of the back-contact photovoltaic module.

With continued reference to FIGS. 1 and 6 , in some embodiments, a width of the second insulating film 6 along the first direction X is greater than a width of the second busbar 7 along the first direction X. In this way, the width of the second insulating film 6 is relatively large, which can effectively achieve electrical isolation between the second busbar 7 and the first ribbon 2.

In some embodiments, the width of the second insulating film 6 along the first direction X is 10 mm to 20 mm, for example, 10 mm, 12 mm, 14 mm, 16 mm, 18 mm, or 20 mm. When the width of the second insulating film 6 is within the above range, the second insulating film 6 can effectively isolate the second busbar 7 from the first ribbon 2 on the fourth solar cell 17, and can also avoid problems such as affecting sunlight absorption by the fourth solar cell 17 and cost increase caused by an excessively wide second insulating film 6.

The width of the second busbar 7 along the first direction X is 8 mm to 15 mm, for example, 8 mm, 10 mm, 12 mm, 14 mm, or 15 mm.

FIG. 10 is a schematic cross-sectional structural diagram of the back-contact photovoltaic module according to an embodiment of the present disclosure.

Referring to FIGS. 1 and 10 , in some embodiments, the back-contact photovoltaic module further includes an encapsulant film 91 and a cover plate 92. The encapsulant film 91 is configured to cover a surface of the cell string 1, and the cover plate 92 is configured to cover a surface of the encapsulant film 91 facing away from the cell string 1.

In some embodiments, the encapsulant film 91 includes a first encapsulating layer and a second encapsulating layer. The first encapsulating layer covers one of a front surface or a back surface of the cell string 1, and the second encapsulating layer covers the other of the front surface or the back surface of the cell string 1. Specifically, at least one of the first encapsulating layer and the second encapsulating layer may be an organic encapsulant film such as a polyvinyl butyral (PVB) film, an ethylene-vinyl acetate (EVA) film, a polyolefin elastomer (POE) film, or a polyethylene terephthalate (PET) film. Alternatively, at least one of the first encapsulating layer and the second encapsulating layer may also be a film such as an EP film, an EPE film, or a PVP film.

The EP film refers to a co-extruded film composed of a laminated EVA film and POE film. The EPE film refers to a co-extruded film formed by sequentially laminating an EVA film, a POE film and an EVA film. The PVP film refers to a co-extruded film formed by sequentially laminating a POE film, an EVA film and a POE film. A manufacturing method of the co-extruded film may be, during a film processing process, sequentially extruding one or more raw materials onto another manufactured film, or bonding manufactured films of different types together.

In some cases, the first encapsulating layer and the second encapsulating layer still have a boundary before lamination, but after the lamination process to form the photovoltaic module, the concept of the first encapsulating layer and the second encapsulating layer no longer exists, that is, the first encapsulating layer and the second encapsulating layer have formed an integral encapsulant film.

In some embodiments, the cover plate 92 may be a cover plate with a light-transmitting function, such as a glass cover plate or a plastic cover plate. Specifically, a surface of the cover plate facing the encapsulant film may be a concave-convex surface or a textured surface including a plurality of protruding structures, thereby increasing the utilization rate of incident light. The cover plate 92 includes a first cover plate and a second cover plate, the first cover plate is opposite to the first encapsulating layer, and the second cover plate is opposite to the second encapsulating layer.

Those of ordinary skill in the art can understand that the above-mentioned various implementations are specific embodiments for realizing the present disclosure, and in practical applications, various changes can be made to the forms and details without departing from the spirit and scope of the present disclosure. Any person skilled in the art can make various changes and modifications without departing from the spirit and scope of the present disclosure. Therefore, the protection scope of the present disclosure should be defined by the claims.

What is claimed is:

1. A back-contact photovoltaic module, comprising:
a plurality of cell strings, wherein a respective cell string of the plurality of cell strings has a leading end and a trailing end opposite to the leading end, and includes a first solar cell at the trailing end and a second solar cell between the first solar cell and the leading end;
at least one first ribbon, a respective first ribbon of the at least one first ribbon extending from the first solar cell to the second solar cell along a first direction from the trailing end to the leading end, and electrically connecting the first solar cell to the second solar cell;
a first insulating film, disposed over the second solar cell and on a side of the respective first ribbon facing away from the second solar cell;
a first busbar, disposed on a side of the first insulating film facing away from the second solar cell; and
at least one second ribbon, a respective second ribbon of the at least one second ribbon including a first portion and a second portion, wherein the first portion is located on the first solar cell and is electrically connected to the first solar cell, and the second portion is located on the side of the first insulating film facing away from the second solar cell and is electrically connected to the first busbar.

2. The back-contact photovoltaic module according to claim 1, wherein the respective second ribbon further includes a connecting portion located between the first portion and the second portion, an extension direction of the connecting portion intersects the first direction, and the second portion and the respective first ribbon on the second solar cell are spaced apart from each other along a second direction intersecting the first direction.

3. The back-contact photovoltaic module according to claim 2, wherein an angle between the extension direction of the connecting portion 53 and the first direction is 20° to 90°.

4. The back-contact photovoltaic module according to claim 2, wherein a length of the connecting portion along the extension direction is 5 mm to 8 mm.

5. The back-contact photovoltaic module according to claim 2, wherein a distance between the second portion and an adjacent first ribbon along the second direction is 3 mm to 8 mm.

6. The back-contact photovoltaic module according to claim 2, wherein a thickness of the respective second ribbon is less than or equal to a thickness of the first ribbon.

7. The back-contact photovoltaic module according to claim 2, wherein a thickness of the first insulating film is 0.1 mm to 0.3 mm.

8. The back-contact photovoltaic module according to claim 2, wherein the respective second ribbon is located between the first insulating film and the first busbar, the first insulating film includes a first flat portion and a first protruding portion, the first protruding portion protrudes in a direction away from the second solar cell, and the respective first ribbon is located between the first protruding portion and the second solar cell; and
wherein a surface of the first protruding portion facing away from the second solar cell and a surface of the first flat portion facing away from the second solar cell form a first recess, and the respective second ribbon is located within the first recess.

9. The back-contact photovoltaic module according to claim 8, wherein the first flat portion is in direct contact with the second solar cell, and the first protruding portion is lifted by the respective first ribbon and protrudes in the direction away from the second solar cell.

10. The back-contact photovoltaic module according to claim 2, wherein the first busbar is located between the first insulating film and the respective second ribbon, the first insulating film includes a first flat portion and a first protruding portion, the first protruding portion protrudes in a direction away from the second solar cell, and the respective first ribbon is located between the first protruding portion and the second solar cell;
wherein the first busbar includes a second flat portion and a second protruding portion, the second flat portion is located on a surface of the first flat portion facing away from the second solar cell, the second protruding portion protrudes in a direction away from the second solar cell, the second protruding portion is located on a surface of the first protruding portion facing away from the second solar cell; and
wherein a surface of the second protruding portion facing away from the second solar cell and a surface of the second flat portion facing away from the second solar cell form a second recess, and the respective second ribbon is located within the second recess.

11. The back-contact photovoltaic module according to claim 1, wherein a spacing is present between the first busbar and the first solar cell.

12. The back-contact photovoltaic module according to claim 1, wherein a length of the first portion along the first direction is 166 mm to 178 mm.

13. The back-contact photovoltaic module according to claim 1, wherein the first insulating film includes a spacing portion and an insulating portion, the spacing portion is located between the first solar cell and the second solar cell, and the insulating portion is located over a surface of the second solar cell.

14. The back-contact photovoltaic module according to claim 1, wherein the first insulating film is a transparent film layer.

15. The back-contact photovoltaic module according to claim 1, wherein a width of the first insulating film along the first direction is greater than a width of the first busbar along the first direction.

16. The back-contact photovoltaic module according to claim 1, wherein a width of the first insulating film along the first direction is 10 mm to 20 mm.

17. The back-contact photovoltaic module according to claim 1, wherein a width of the first busbar along the first direction is 8 mm to 15 mm.

18. The back-contact photovoltaic module according to claim 1, wherein the respective cell string further includes a third solar cell disposed at the leading end and a fourth solar cell connected to the third solar cell, and a first ribbon of the at least one first ribbon is configured to electrically connect the third solar cell to the fourth solar cell;
wherein the back-contact photovoltaic module further includes:
a second busbar, electrically connecting third solar cells of two cell strings arranged along a second direction, the second busbar being located over the fourth solar cell;
a second insulating film, disposed over the fourth solar cell and located between the second busbar and the fourth solar cell; and
a third ribbon, including a first part and a second part, wherein the first part is located on the third solar cell and is electrically connected to the third solar cell, and the second part is located on a surface of the second insulating film facing away from the fourth solar cell and is electrically connected to the second busbar.

19. The back-contact photovoltaic module according to claim 10, wherein the third ribbon further includes a connecting part located between the first part and the second part, an extension direction of the connecting part intersects the first direction, and the second part and the first ribbon on the fourth solar cell are spaced apart from each other along the second direction.

20. The back-contact photovoltaic module according to claim 1, further comprising:
at least one encapsulant film, configured to cover surfaces of the plurality of cell strings; and
at least one cover plate, configured to cover a surface of the at least one encapsulant film facing away from the plurality of cell strings.
